(19) United States
(12) Patent Application Publication
(10) Pub. No.: US 2026/0114060 A1
(43) Pub. Date: Apr. 23, 2026

(54) IMAGE SENSOR

(71) Applicant: Samsung Electronics Co., Ltd., Suwon-si (KR)

(72) Inventors: Seong Hoon Ko, Suwon-si (KR); Sung Chul Kim, Suwon-si (KR); Jae Ho Kim, Suwon-si (KR); Yong Hee Park, Suwon-si (KR); Sung Jun In, Suwon-si (KR); Ha Na Choi, Suwon-si (KR)

(21) Appl. No.: 19/296,260

(22) Filed: Aug. 11, 2025

(30) Foreign Application Priority Data
Oct. 18, 2024 (KR) 10-2024-0142740

(51) Int. Cl. H10F 39/00; H10F 39/18

(52) U.S. Cl. CPC H10F 39/80373; H10F 39/182; H10F 39/807; H10F 39/809; H10F 39/811

(57) ABSTRACT

An image sensor is provided. The image sensor includes a substrate that includes a first surface and a second surface opposing the first surface, a first pixel region comprising a first photoelectric conversion region (PD) in the substrate, a second pixel region comprising a second photoelectric conversion region (PD) in the substrate, a PD separation pattern between the first PD and the second PD, a transfer gate structure comprising a first lower part extending into the substrate from the first surface, and a first upper part protruding beyond the first surface, and a control gate structure comprising a second lower part extending into the substrate from the first surface, and a second upper part protruding beyond the first surface, wherein the PD separation pattern penetrates the substrate, wherein the first upper part is spaced apart from the second upper part in a first direction parallel to the first surface, wherein the transfer gate structure and the control gate structure are disposed in the first pixel region, and wherein the image sensor is configured to receive light from the second surface.

### CROSS-REFERENCE TO RELATED APPLICATION(S)

This application claims priority under 35 U.S.C. 119 to Korean Patent Application No. 10-2024-0142740, filed on Oct. 18, 2024 in the Korean Intellectual Property Office and all the benefits accruing therefrom under 35 U.S.C. 119, the contents of which in its entirety are herein incorporated by reference.

### BACKGROUND

The image sensor is one of semiconductor elements that convert optical information into an electric signal. Such an image sensor may include a charge coupled device (CCD) image sensor and a complementary metal-oxide semiconductor (CMOS) image sensor.

The image sensor may be configured in the form of a package. The package protects the image sensor, and may be configured as a structure which allows light to enter a photo-receiving surface or a sensing region of the image sensor.

### SUMMARY

Aspects of the present disclosure provide an image sensor having improved performance and integration.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, an image sensor includes a substrate which includes a first surface and a second surface opposing the first surface, a first pixel region comprising a first photoelectric conversion region (PD) in the substrate, a second pixel region comprising a second photoelectric conversion region (PD) in the substrate, a PD separation pattern between the first PD and the second PD, a transfer gate structure comprising a first lower part extending into the substrate from the first surface, and a first upper part protruding beyond the first surface, and a control gate structure comprising a second lower part extending into the substrate from the first surface, and a second upper part protruding beyond the first surface, wherein the PD separation pattern penetrates the substrate, wherein the first upper part is spaced apart from the second upper part in a first direction parallel to the first surface, wherein the transfer gate structure and the control gate structure are disposed in the first pixel region, and wherein the image sensor is configured to receive light from the second surface.

According to an aspect of the present disclosure, an image sensor includes a substrate comprising a first surface and a second surface opposing the first surface, a first pixel region comprising a first photoelectric conversion region (PD) in the substrate, a second pixel region comprising a second photoelectric conversion region (PD) in the substrate, a third pixel region comprising a third photoelectric conversion region (PD) in the substrate, a fourth pixel region comprising a fourth photoelectric conversion region (PD) in the substrate, a PD separation pattern separating the first to fourth PDs to each other, a single color filter on the first to fourth PDs, a floating diffusion region configured to store photocharges generated by the first to fourth PDs, a first transfer gate structure comprising a first lower part extending into the substrate from the first surface, and a first upper part protruding beyond the first surface, and a first control gate structure comprising a second lower part extending into the substrate from the first surface, and a second upper part protruding beyond the first surface, wherein the PD separation pattern penetrates the substrate, wherein the first upper part is spaced apart from the second upper part in a first direction parallel to the first surface, wherein the first transfer gate structure and the first control gate structure are disposed in the first pixel region, wherein the first to fourth pixel regions are sequentially arranged in a clockwise direction in a plan view, and wherein the image sensor is configured to receive light from the second surface.

### BRIEF DESCRIPTION OF THE DRAWINGS

The above and other aspects and features of the present disclosure will become more apparent by describing in detail exemplary implementations thereof with reference to the attached drawings, in which:

FIG. 1 is an exemplary circuit diagram for explaining a shared pixel structure of a pixel array of an image sensor according to some implementations.

FIG. 2 is a plan view for explaining a pixel array of an image sensor according to some implementations.

FIG. 3 is a schematic cross-sectional view taken along A-A of FIG. 2.

FIG. 4 is a schematic cross-sectional view taken along B-B of FIG. 2.

FIG. 5 is a graph for explaining the performance of an image sensor according to some implementations.

FIGS. 6 and 7 are various cross-sectional views for explaining an image sensor according to some implementations.

FIG. 8 is a plan view for explaining a pixel array of an image sensor according to some implementations.

FIG. 9 is a schematic cross-sectional view taken along C-C of FIG. 8.

FIGS. 10 to 13 are various plan views for explaining a pixel array of the image sensor according to some implementations.

FIGS. 14 and 15 are various layout diagrams for explaining a pixel array of an image sensor according to some implementations.

FIG. 16 is a schematically exploded perspective view for explaining an image sensor according to some implementations.

FIG. 17 is a schematic cross-sectional view for explaining the image sensor of FIG. 16.

### DETAILED DESCRIPTION

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present disclosure.

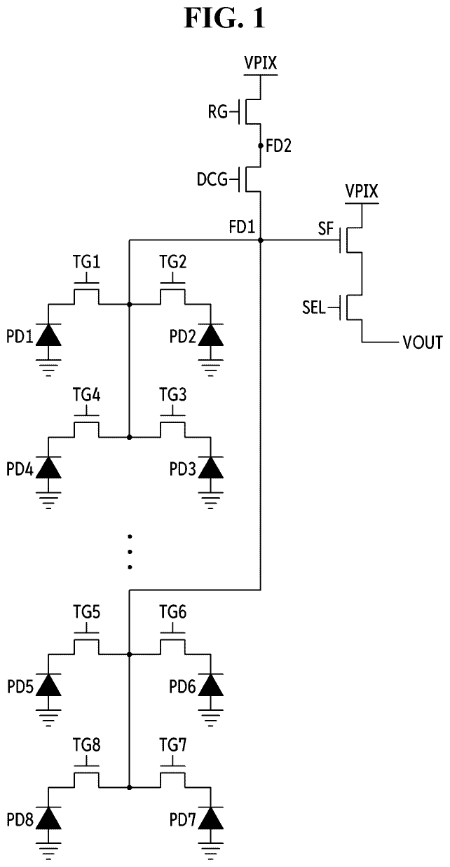

Hereinafter, an image sensor according to exemplary implementations will be described referring to FIGS. 1 to 17.

FIG. 1 is an exemplary circuit diagram for explaining a shared pixel structure of a pixel array of an image sensor according to some implementations.

Referring to FIG. 1, the pixel array may include a plurality of photodiodes PD1 to PD8, a plurality of transfer transistors TG1 to TG8, a first floating diffusion region FD1, a second floating diffusion region FD2, a reset transistor RG, a source follower transistor SF, a selection transistor SEL, and a dual conversion gain transistor DCG.

The shared pixel structure may include the plurality of photodiodes PD1 to PD8 including a first photodiode PD1, a second photodiode PD2, a third photodiode PD3, a fourth photodiode PD4, a fifth photodiode PD5, a sixth photodiode PD6, a seventh photodiode PD7, and an eighth photodiode PD8. The plurality of photodiodes PD1 to PD8 may be divided into two PD groups: a first PD group in which the first to fourth photodiodes PD1 to PD4 are arranged in a 2×2 matrix centered around a first shared floating diffusion region; and a second PD group in which the fifth to eighth photodiodes PD5 to PD8 are arranged in a 2×2 matrix centered around a second shared floating diffusion region. In this case, the first shared floating diffusion region and the second shared floating diffusion region may be connected via a connection line or a connection area and form a first floating diffusion region FD1. In some implementations, the plurality of photodiodes PD1 to PD8 may also be configured as a single PD group arranged around the first floating diffusion region FD1. In some implementations, the shared pixel structure may further include a third PD group comprising additional four photodiodes connected to the first floating diffusion region FD1, and a fourth PD group comprising the other additional four photodiodes connected to the second floating diffusion region FD2.

Each pixel described in the present disclosure may consist of one photodiode and one microlens, two photodiodes and one microlens, or four photodiodes and one microlens. That is, the plurality of photodiodes PD1 to PD8 may be included in eight pixels, four pixels, or two pixels. The plurality of transfer transistors TG1 to TG8 may include a first transfer transistor TG1, a second transfer transistor TG2, a third transfer transistor TG3, a fourth transfer transistor TG4, a fifth transfer transistor TG5, a sixth transfer transistor TG6, a seventh transfer transistor TG7, and an eighth transfer transistor TG8. However, the number of photodiodes and the number of transfer transistors are not limited thereto.

Each of the plurality of photodiodes PD1 to PD8 may be formed by forming an n-type semiconductor region on a substrate formed with a p-type semiconductor region and convert incident light into electric charges. Each of the plurality of photodiodes PD1 to PD8 may be coupled to a corresponding transfer transistor that transfers the generated and accumulated electric charges to the corresponding floating diffusion region. Because the floating diffusion region is a region for switching the electric charges to voltage and has a parasitic capacitance, the electric charges may be accumulatively stored.

In some implementations, the first floating diffusion region FD1 may be connected to the second floating diffusion region FD2 by a dual conversion gain transistor DCG to adjust a combined capacitance. In some implementations, the second floating diffusion region FD2 may be a doping region and be connected to a capacitor. The capacitor may be a metal-insulator-metal capacitor.

One end of each of the plurality of transfer transistors TG1 to TG8 may be connected to a corresponding photodiode of the plurality of photodiodes PD1 to PD8. The other end of each of the plurality of transfer transistors TG1 to TG8 may be connected to the first floating diffusion region or the second shared floating diffusion region. Each of the plurality of transfer transistors TG1 to TG8 may be formed of a transistor driven by a predetermined bias, e.g., transfer signals. The transfer signals may be applied to a gate of each of the transfer transistors TG1 to TG8 to transfer the electric charges generated from the corresponding photodiode of the plurality of photodiodes PD1 to PD8 to the first floating diffusion region or the second shared floating diffusion region according to the transfer signals.

The source follower transistor SF may amplify a change in electrical potential of the first floating diffusion region FD1 to which the electric charges are sent from the plurality of photodiodes PD1 to PD8 and output it to an output line VOUT. When the source follower transistor SF is turned on, a predetermined electrical potential provided to a drain of the source follower transistor SF, for example, a power supply voltage VPIX, may be sent to a drain region of the selection transistor SEL. In some implementations, a plurality of source follower transistors SFs may be connected to the first floating diffusion region FD1.

The selection transistor SEL may select a pixel to be read in units of a row. The selection transistor SEL may be made up of a transistor that is driven by a selection line that applies a predetermined bias, e.g., a row selection signal. The row selection signal may be applied through a gate of the selection transistor SEL.

The reset transistor RG may periodically reset the first floating diffusion region FD1. When the reset transistor RG is turned on by a reset signal, a predetermined electrical potential provided to a drain of the reset transistor RG, for example, the power supply voltage VPIX, may be sent to the first floating diffusion region FD1.

The dual conversion gain transistor DCG may adjust a conversion gain. For example, the conversion gain may be adjusted, by applying dual gain signal of a logic high level or applying a dual gain signal of a logic low level to a dual conversion gate of the dual conversion transistor DCG. The dual conversion gain transistor DCG may be provided between the first floating diffusion region FD1 and the second floating diffusion region FD2. The conversion gain may be adjusted, by adjusting the combined capacitance corresponding to the first floating diffusion region FD1 and the second floating diffusion region FD2 depending on whether the dual conversion gain transistor DCG is driven.

Although FIG. 1 shows an example in which eight photodiodes PD1 to PD8 electrically share the first floating diffusion region FD1, the present disclosure is not limited thereto. That is, the number of photodiodes that electrically share the first floating diffusion region FD1 is not limited to that shown. In some implementations, the pixel array comprises a non-shared pixel structure where one photodiode is connected to the first floating diffusion region FD1.

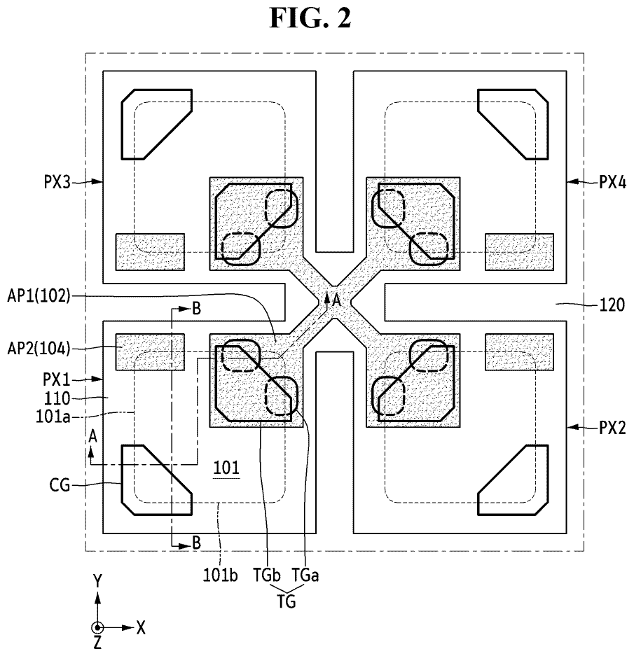

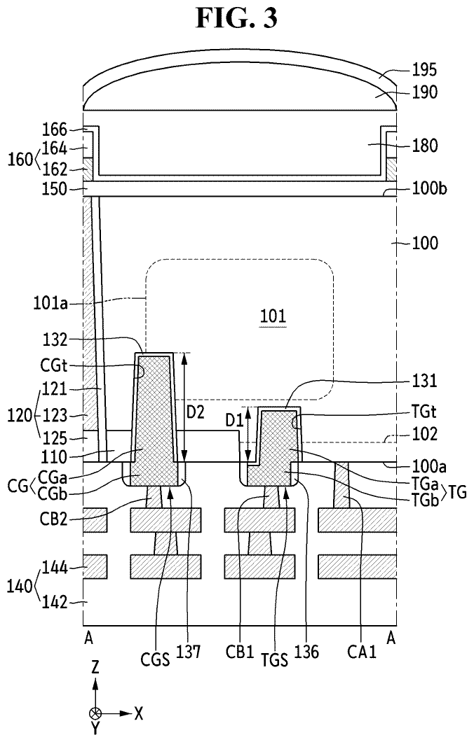

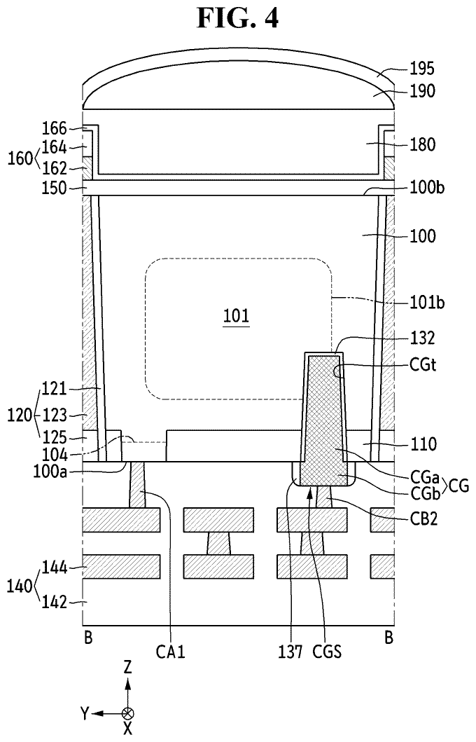

FIG. 2 is a plan view for explaining a pixel array of an image sensor according to some implementations. FIG. 3 is a schematic cross-sectional view taken along A-A of FIG. 2. FIG. 4 is a schematic cross-sectional view taken along B-B of FIG. 2.

Referring to FIGS. 1 to 4, the image sensor according to some implementations includes a first substrate 100, an element separation pattern 110, a PD separation pattern 120, a photoelectric conversion region 101, a first impurity region 102, a second impurity region 104, a transfer gate structure TGS, a control gate structure CGS, a first wiring structure 140, a surface insulating film 150, a grid pattern 150, a color filter 180, and a microlens 190.

The first substrate 100 may be a semiconductor substrate. For example, the first substrate 100 may be bulk silicon or SOI (silicon-on-insulator). The first substrate 100 may be a silicon substrate or may include other substances, for example, silicon germanium, indium antimonide, lead tellurium compounds, indium arsenic, indium phosphide, gallium arsenide or gallium antimonide. Alternatively, the first substrate 100 may be one in which an epitaxial layer is formed on a base substrate.

The first substrate 100 may include a first surface 100a and a second surface 100b that are opposite to each other. In the implementations to be described below, the first surface 100a may be referred to as a front side of the first substrate 100, and the second surface 100b may be referred to as a back side of the first substrate 100. In some implementations, the second surface 100b of the first substrate 100 may be a photo-receiving surface to which light is incident. That is, the image sensor according to some implementations may be a back-illuminated (BSI) image sensor.

In some implementations, the first substrate 100 may have a first conductive type. In the implementations described below, the first conductive type will be described as a p-type, but this is merely an example, and it goes without saying that the first conductive type may be an n-type.

The first substrate 100 may include a plurality of pixel regions PX1 to PX4. Each of the pixel regions PX1 to PX4 may be a region of the first substrate 100 constituting a unit pixel PX of FIG. 1. The pixel regions PX1 to PX4 may be arranged two-dimensionally (e.g., in the form of a matrix) along a horizontal plane (e.g., an XY plane).

For example, the pixel regions PX1 to PX4 may include a first pixel region PX1, a second pixel region PX2, a third pixel region PX3, and a fourth pixel region PX4 that are adjacent to one another. The first pixel region PX1 and the second pixel region PX2 may be adjacent to each other in the first direction X. The first pixel region PX1 and the third pixel region PX3 may be adjacent to each other in a second direction Y that intersects the first direction X. The second pixel region PX2 and the fourth pixel region PX4 may be adjacent to each other in the second direction Y, and the third pixel region PX3 and the fourth pixel region PX4 may be adjacent to each other in the first direction X. That is, the first pixel region PX1 and the fourth pixel region PX4 may be adjacent to each other in a diagonal direction between the first direction X and the second direction Y.

An element separation pattern 110 may be formed inside the first substrate 100. The element separation pattern 110 may be adjacent to (or in contact with) the first surface 100a of the first substrate 100. The element separation pattern 110 may define active regions AP1 and AP2 in each of the pixel regions PX1 to PX4 adjacent to the first surface 100a. For example, shallow trenches (hereinafter, element separation trenches) extending from the first surface 100a to define the active regions AP1 and AP2 may be formed inside the first substrate 100. The element separation pattern 110 may fill at least a part of the element separation trench. The shapes, sizes, numbers, placement and the like of the active regions AP1 and AP2 are merely exemplary, and are not limited to those shown in the drawings.

The element separation pattern 110 may include an insulating material, for example, but not limited to, at least one of silicon oxide, silicon nitride, silicon oxynitride or a combination thereof. As an example, the element separation pattern 110 may include a silicon oxide film. Although the element separation pattern 110 is only shown as being a single film, this is merely an example, and the element separation pattern 110 may be a multi-film formed by stacking multiple material films.

In some implementations, the active regions AP1 and AP2 of each of the pixel regions PX1 to PX4 may include a first active pattern AP1 and a second active pattern AP2. The first active pattern AP1 and the second active pattern AP2 may be separated from each other by the element separation pattern 110.

The PD separation pattern 120 may be formed inside the first substrate 100. The PD separation pattern 120 may define a plurality of pixel regions PX1 to PX4 inside the first substrate 100. For example, a deep trench (hereinafter, pixel separation trench) that defines the plurality of pixel regions PX1 to PX4 may be formed in the first substrate 100. The pixel separation trench may be formed in a lattice shape from a planar view point (e.g., the XY plane), and may surround each of the pixel regions PX1 to PX4. The PD separation pattern 120 may fill at least a part of the pixel separation trench.

The PD separation pattern 120 may prevent photocharges generated in a specific unit pixel (e.g., the first unit pixel G1) from moving to adjacent other unit pixels (e.g., second to fourth unit pixels PX2 to PX4) due to a random drift. Furthermore, the PD separation pattern 120 may prevent an optical cross-talk in which light incident on a specific unit pixel (e.g., the first unit pixel PX1) is incident on other adjacent unit pixels (e.g., the second to fourth unit pixels PX2 to PX4).

In some implementations, a width of the PD separation pattern 120 may decrease from the first surface 100a toward the second surface 100b. Here, the width of the PD separation pattern 120 means a width measured along a horizontal plane (e.g., the XY plane). This may be due to the fact that the etching process for forming the PD separation pattern 120 is performed toward the first surface 100a of the first substrate 100. For example, the PD separation pattern 120 may be a frontside DTI (FDTI) formed by a deep trench isolation (DTI) process on the front side (i.e., the first surface 100a) of the first substrate 100.

In some implementations, the PD separation pattern 120 may completely penetrate the first substrate 100. For example, the PD separation pattern 120 may be adjacent to (or in contact with) both the first surface 100a and the second surface 100b.

In some implementations, the PD separation pattern 120 may include a liner insulating film 121, a gap-fill film 123, and a buried insulating film 125.

The liner insulating film 121 may be stacked on the inner wall of the first substrate 100. The liner insulating film 121 may be interposed between the first substrate 100 and the gap-fill film 123. For example, the liner insulating film 121 may extend along the profile of the inner wall of the first substrate 100.

The liner insulating film 121 may include at least one of insulating materials, for example, but not limited to, at least one of silicon oxide, silicon nitride, silicon oxynitride, silicon carbonitride, silicon oxycarbonitride or a combination thereof. Although the liner insulating film 121 is shown to be a single film, this is merely exemplary, and the liner insulating film 121 may be a multi-layer film. Although a boundary between the element separation pattern 110 and the liner insulating film 121 is shown as being present, this is merely exemplary, and the boundary between the element separation pattern 110 and the liner insulating film 121 may not be present. For example, when the element separation pattern 110 and the liner insulating film 121 include the same material (e.g., silicon oxide film), the boundary between the element separation pattern 110 and the liner insulating film 121 may not be distinguished.

A gap-fill film 123 may be stacked on the liner insulating film 121. The gap-fill film 123 may fill at least a part of the region of the PD separation pattern 120 that remains after the liner insulating film 121 is filled. In some implementations, the gap-fill film 123 may be spaced apart from the first surface 100a, and may be in contact with the second surface 100b.

The gap-fill film 123 may include, but not limited to, a conductive material, for example, at least one of an undoped polysilicon film, an undoped silicon germanium film, a polysilicon film doped with impurities, a silicon germanium film doped with impurities or a metal film. As an example, the gap-fill film 123 may include a polysilicon film doped with p-type impurities (e.g., boron (B)) or n-type impurities (e.g., phosphorus (P)). The gap-fill film 123 may also include an oxide material, for example, at least one of an aluminum oxide, a hafnium oxide, silicon oxide, a tantalum oxide or a tantalum silicon oxide.

In some implementations, a negative (−) bias voltage may be applied to the gap-fill film 123. Such a gap-fill film 123 may capture holes that may exist on the surface of the first substrate 100 adjacent to the PD separation pattern 120, thereby improving dark current characteristics of the image sensor.

The buried insulating film 125 may be stacked on the liner insulating film 121 and the buried insulating film 125. The gap-fill film 123 may be spaced apart from the first surface 100a by the buried insulating film 125. In some implementations, a part of the liner insulating film 121 may be interposed between the element separation pattern 110 and the buried insulating film 125.

Although a depth at which the buried insulating film 125 is formed is shown as being the same as a depth at which the element separation pattern 110 is formed on the basis of the first surface 100a, this is merely exemplary, and it goes without saying that the depth at which the buried insulating film 125 is formed may be different from the depth at which the element separation pattern 110 is formed.

The buried insulating film 125 may include, but not limited to, at least one of an insulating material, for example, silicon oxide, silicon nitride, silicon oxynitride or a combination thereof. Although the buried insulating film 125 is shown as being a single film, this is merely exemplary, and the buried insulating film 125 may be a multi-layer film. Although a boundary between the liner insulating film 121 and the buried insulating film 125 is shown as being present, this is merely exemplary, and the boundary between the liner insulating film 121 and the buried insulating film 125 may not be present. For example, when the liner insulating film 121 and the buried insulating film 125 include the same material (e.g., silicon oxide film), the boundary between the liner insulating film 121 and the buried insulating film 125 may not be distinguished.

The photoelectric conversion region 101 may be formed inside the first substrate 100. The photoelectric conversion region 101 may be formed inside each of the pixel regions PX1 to PX4. The photoelectric conversion region 101 may have a second conductive type different from the first conductive type. For example, the photoelectric conversion region 101 may be formed by ion-implantation of n-type impurities into the p-type first substrate 100. The photoelectric conversion region 101 and the region of the first substrate 100 surrounding it may be provided as the photoelectric conversion element PD of FIG. 1. In the implementations to be described below, the photoelectric conversion region 101 is also referred to as a PD.

In some implementations, the photoelectric conversion region 101 may be spaced apart from the first surface 100a of the first substrate 100. For example, the photoelectric conversion region 101 may be an n-type impurity region formed in the first substrate 100 spaced apart from the first surface 100a.

The first impurity region 102 may be formed inside the first substrate 100 adjacent to the first surface 100a. For example, the first impurity region 102 may be formed inside the first active pattern AP1. The first impurity region 102 may have the second conductivity type. For example, the first impurity region 102 may be an n-type impurity region formed by ion-implantation of n-type impurities into the first active pattern AP1. The first impurity region 102 may be spaced apart from the photoelectric conversion region 101. In some implementations, at least a part of the first impurity region 102 may be spaced apart from the photoelectric conversion region 101 in a third direction Z that intersects the first surface 100a. The first impurity region 102 may be provided as the floating diffusion region FD of FIG. 1.

In some implementations, the depth at which the first impurity region 102 is formed may be smaller than the depth at which the element separation pattern 110 is formed on the basis of the first surface 100a.

In some implementations, the first impurity region 102 may be disposed in a center surrounded by the first to fourth pixel regions PX1 to PX4. In some implementations, the first to fourth pixel regions PX1 to PX4 may share a single color filter. For example, the single color filter may be disposed on the first to fourth pixel regions PX1 to PX4.

The second impurity region 104 may be formed inside the first substrate 100 adjacent to the first surface 100a. For example, the second impurity region 104 may be formed inside the second active pattern AP2. The second impurity region 104 may have the first conductivity type. For example, the second impurity region 104 may be a high-concentration p-type impurity region formed by ion-implantation of p-type impurity of a high concentration into the second active pattern AP2. The second impurity region 104 may be spaced apart from the photoelectric conversion region 101. The second impurity region 104 may be provided as a ground region to which a ground voltage is applied.

The transfer gate structure TGS may be formed on the first surface 100a of the first substrate 100. The transfer gate structure TGS may be formed on the first active pattern AP1. The transfer gate structure TGS may be adjacent to the first impurity region 102. For example, the first impurity region 102 may be formed inside the first active pattern AP1 on a side surface of the transfer gate structure TGS.

In some implementations, the transfer gate structure TGS may include a transfer gate dielectric film 131, a transfer gate electrode TG, and a transfer gate spacer 136.

The transfer gate dielectric film 131 may be interposed between the first substrate 100 and the transfer gate electrode TG. The transfer gate dielectric film 131 may include a dielectric material, for example, at least one of silicon oxide, silicon oxynitride, silicon nitride, or a high-k material having a higher dielectric constant than silicon oxide. The high-k material may include, for example, but not limited to, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide or lead zinc niobate.

The transfer gate electrode TG may be stacked on the transfer gate dielectric film 131. The transfer gate electrode TG may include a conductive material, for example, but not limited to, at least one of a metal film, a metal silicide film, an undoped polysilicon film, an undoped silicon germanium film, a polysilicon film doped with impurities or a silicon germanium film doped with impurities. As an example, the transfer gate electrode TG may include a polysilicon film doped with n-type impurities. The transfer gate electrode TG may be provided as the gate of the transfer transistor TX of FIG. 1.

The transfer gate spacer 136 may extend along the side surface of the transfer gate electrode TG. The transfer gate spacer 136 may include an insulating material, for example, but not limited to, at least one of silicon oxide, silicon nitride, silicon oxynitride, silicon oxycarbide, silicon boronitride, silicon boron carbonitride, silicon oxycarbonitride, and combinations thereof.

In some implementations, at least a part of the transfer gate structure TGS may extend into the first substrate 100 toward the photoelectric conversion region 101 in the third direction Z. For example, a first gate trench TGt may be formed in the first substrate 100. The first gate trench TGt may extend from the first surface 100a. The first gate trench TGt may be spaced apart from the photoelectric conversion region 101 in the third direction Z. At least a part of the transfer gate structure TGS may fill the first gate trench TGt. For example, the transfer gate dielectric film 131 may extend conformally along the profile of the first gate trench TGt. The transfer gate electrode TG may fill the region of the first gate trench TGt that remains after being filled with the transfer gate dielectric film 131.

In some implementations, the transfer gate electrode TG may include a first lower electrode TGa and a first upper electrode TGb. The first lower electrode TGa may be disposed inside the first gate trench TGt. The first upper electrode TGb is connected to the first lower electrode TGa, and may protrude beyond the first surface 100a. That is, the first lower electrode TGa may be a region of the transfer gate electrode TG located in the first substrate 100, and the first upper electrode TGb may be a region of the transfer gate electrode TG located outside the first substrate 100. For example, the transfer gate structure TGS may include a first lower part extending into the substrate 100, and a first upper part protruding beyond the first surface 100a.

The transfer gate dielectric film 131 may be interposed between the first substrate 100 and the first lower electrode TGa, and between the first substrate 100 and the first upper electrode TGb. The transfer gate spacer 136 may extend along a side surface of the first upper electrode TGb.

In some implementations, a depth at which the transfer gate structure TGS is formed may be greater than a depth at which the first impurity region 102 is formed on the basis of the first surface 100a. For example, as shown in FIG. 3, a depth D1 of the first gate trench TGt may be greater than a depth at which the first impurity region 102 is formed on the basis of the first surface 100a.

A control gate structure CGS may be formed on the first surface 100a of the first substrate 100. The control gate structure CGS may be spaced apart from the floating diffusion region FD and the transfer gate structure TGS. For example, the control gate structure CGS may be formed on the element separation pattern 110. In FIG. 2, although the transfer gate structure TGS and the control gate structure CGS are only shown to be spaced apart in a diagonal direction between the first direction X and the second direction Y, this is merely exemplary, and it goes without saying that the form in which the transfer gate structure TGS and the control gate structure CGS are disposed may vary.

In some implementations, the control gate structure CGS may include a control gate dielectric film 132, a control gate electrode CG, and a control gate spacer 137.

The control gate dielectric film 132 may be interposed between the first substrate 100 and the control gate electrode CG. The control gate dielectric film 132 may include at least one of a dielectric material, for example, silicon oxide, silicon oxynitride, silicon nitride, or the high-dielectric constant material having a dielectric constant greater than that of silicon oxide. The control gate dielectric film 132 may include the same material as the transfer gate dielectric film 131, or may include a different material from the transfer gate dielectric film 131.

The control gate electrode CG may be stacked on the control gate dielectric film 132. The control gate electrode CG may include at least one of a conductive material, for example, but not limited to, a metal film, a metal silicide film, an undoped polysilicon film, an undoped silicon germanium film, a polysilicon film doped with impurities or a silicon germanium film doped with impurities. The control gate electrode CG may include the same material as the transfer gate electrode TG, or may include a different material from the transfer gate electrode TG.

The control gate spacer 137 may extend along a side surface of the control gate electrode CG. The control gate spacer 137 may include, for example, an insulating material, but not limited to, at least one of silicon oxide, silicon nitride, silicon oxynitride, silicon oxycarbide, silicon boronitride, silicon boron carbonitride, silicon oxycarbonitride, and combinations thereof. The control gate spacer 137 may include the same material as the transfer gate spacer 136, and may include a different material from the transfer gate spacer 136.

At least a part of the control gate structure CGS may be adjacent to the photoelectric conversion region 101. For example, a second gate trench CGt may be formed across the element separation pattern 110 and the first substrate 100. The second gate trench CGt may come into contact with the photoelectric conversion region 101. At least a part of the control gate structure CGS may fill the second gate trench CGt. For example, the control gate dielectric film 132 may extend conformally along the profile of the second gate trench CGt. The control gate electrode CG may fill the region of the second gate trench CGt that remains after being filled with the control gate dielectric film 132.

From a planar view point parallel to the first surface 100a, at least a part of the photoelectric conversion region 101 may be interposed between the transfer gate structure TGS and the control gate structure CGS. For example, as shown in FIG. 2, from a planar view point, a part of the photoelectric conversion region 101 may be interposed between the transfer gate structure TGS and the control gate structure CGS in a diagonal direction between the first direction X and the second direction Y.

In some implementations, at least a part of the control gate structure CGS may come into contact with a side surface of the photoelectric conversion region 101. For example, the photoelectric conversion region 101 may include a first side surface 101a and a second side surface 101b that intersect each other. As an example, the first side surface 101a may intersect the first direction X, and the second side surface 101b may intersect the second direction Y. The second gate trench CGt may come into contact with at least one of the first side surface 101a or the second side surface 101b. In some implementations, the second gate trench CGt may come into contact with both the first side surface 101a and the second side surface 101b.

In some implementations, a part of the control gate structure CGS may overlap the photoelectric conversion region 101 in the third direction Z, and another part of the control gate structure CGS may not overlap the photoelectric conversion region 101 in the third direction Z. For example, as shown in FIG. 2, from a planar view point, the photoelectric conversion region 101 may not completely surround the control gate structure CGS.

In some implementations, the control gate electrode CG may include a second lower electrode CGa and a second upper electrode CGb. The second lower electrode CGa may be disposed inside the second gate trench CGt. The second upper electrode CGb is connected to the second lower electrode CGa, and may protrude beyond the first surface 100a. That is, the second lower electrode CGa may be a region of the control gate electrode CG located in the first substrate 100, and the second upper electrode CGb may be a region of the control gate electrode CG located outside the first substrate 100. For example, the control gate structure CGS may include a second lower part extending into the substrate 100, and a second upper part protruding beyond the first surface 100a.

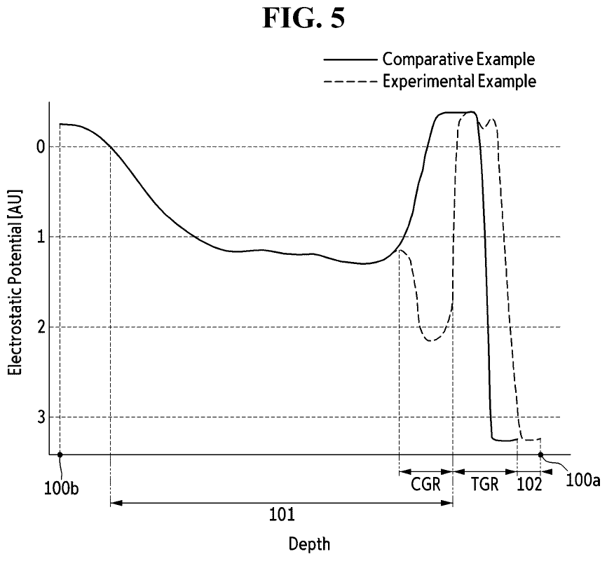

In some implementations, a positive (+) bias voltage may be applied to the control gate electrode CG at the time of an off-operation of the transfer gate structure TGS. Accordingly, a full well capacity (FWC) of the photoelectric conversion element PD due to the photoelectric conversion region 101 may be improved. This will be described in more detail later in the description of FIG. 5.

In some implementations, the voltage applied to the control gate electrode CG at the time of an on-operation of the transfer gate structure TGS may be lower than the voltage applied to the control gate electrode CG at the time of the off-operation of the transfer gate structure TGS. As an example, a negative (-) bias voltage may be applied to the control gate electrode CG at the time of the on-operation of the transfer gate structure TGS.

The control gate dielectric film 132 may be interposed between the first substrate 100 and the second lower electrode CGa, and between the first substrate 100 and the second upper electrode CGb. The control gate spacer 137 may extend along the side surface of the second upper electrode CGb.

In some implementations, the depth at which the control gate structure CGS is formed may be greater than the depth at which the transfer gate structure TGS is formed, on the basis of the first surface 100a. For example, as shown in FIG. 3, a depth D1 of the first gate trench TGt may be greater than a depth D2 of the second gate trench CGt on the basis of the first surface 100a.

In some implementations, one end of the control gate structure CGS (e.g., the upper end of the control gate structure CGS in FIG. 3) may be located at a level between the upper face of the photoelectric conversion region 101 and the lower face of the photoelectric conversion region 101. For example, as shown in FIG. 3, on the basis of the first surface 100a, the depth D2 of the second gate trench CGt may be greater than a minimum depth at which the photoelectric conversion region 101 is formed (e.g., a distance between the first surface 100a and the lower face of the photoelectric conversion region 101 in FIG. 3), and may be smaller than a maximum depth at which the photoelectric conversion region 101 is formed (e.g., a distance between the first surface 100a and the upper face of the photoelectric conversion region 101 in FIG. 3).

In some implementations, the depth D2 of the second gate trench CGt may be about 10% to about 50%, or about 20% to about 30% of the height (or a thickness in the third direction Z) of the first substrate 100. For example, when the thickness of the first substrate 100 in the third direction Z is about 4 μm, the depth D2 of the second gate trench CGt may be about 0.4 μm to about 2 μm, or about 0.8 μm to about 1.2 μm. The control performance and process difficulty required by the control gate electrode CG may be efficiently provided within the above range.

In some implementations, a width of the first lower part of transfer gate structure TGS at the first surface 100a in the first direction X may vary from −10% to +10% of a width of the second lower part of the control gate structure CGS at the first surface 100a in the first direction X.

In some implementations, the width of the first lower part of transfer gate structure TGS at the first surface 100a in the first direction X may vary from-5% to +5% of the width of the second lower part of the control gate structure CGS at the first surface 100a in the first direction X.

In some implementations, a width of the first upper part of transfer gate structure TGS at the first surface 100a in the first direction X may vary from −10% to +10% of a width of the second upper part of the control gate structure CGS at the first surface 100a in the first direction X.

In some implementations, the width of the first upper part of transfer gate structure TGS at the first surface 100a in the first direction X may vary from −5% to +5% of the width of the second upper part of the control gate structure CGS at the first surface 100a in the first direction X.

The first wiring structure 140 may be formed on the first surface 100a of the first substrate 100. The first wiring structure 140 may include a plurality of wiring patterns. For example, the first wiring structure 140 may include a first inter-wiring insulating film 142 on the first surface 100a, and first wiring patterns 144 in the first inter-wiring insulating film 142. In FIGS. 3 and 4, the shape, arrangement, number of layers, and the like of the first wiring patterns 144 are merely exemplary, and are not limited thereto.

The first wiring structure 140 may be electrically connected to the first impurity region 102, the second impurity region 104, the transfer gate structure TGS, and/or the control gate structure CGS.

For example, a first source/drain contact CA1 connected to the first impurity region 102 may be formed inside the first inter-wiring insulating film 142. The first wiring patterns 144 may be electrically connected to the first impurity region 102 through the first source/drain contact CA1.

For example, a second source/drain contact CA2 connected to the second impurity region 104 may be formed in the first inter-wiring insulating film 142. The first wiring patterns 144 may be electrically connected to the second impurity region 104 through the second source/drain contact CA2.

For example, a first gate contact CB1 connected to the transfer gate electrode TG may be formed in the first inter-wiring insulating film 142. The first wiring patterns 144 may be electrically connected to the transfer gate structure TGS through the first gate contact CB1.

For example, a second gate contact CB2 connected to the control gate electrode CG may be formed in the first inter-wiring insulating film 142. The first wiring patterns 144 may be electrically connected to the control gate structure CGS through the second gate contact CB2.

A surface insulating film 150 may be formed on the second surface 100b of the first substrate 100. The surface insulating film 150 may extend conformally along the second surface 100b of the first substrate 100. The surface insulating film 150 may include at least one of insulating materials, for example, but not limited to, silicon oxide, silicon nitride, silicon oxynitride, aluminum oxide, hafnium oxide, and combinations thereof.

The surface insulating film 150 is provided as an anti-reflection film, and may prevent reflection of light incident on the second surface 100b, which is the photo-receiving surface. Accordingly, the photo-receiving rate of the photoelectric conversion region 101 may be improved. Alternatively, the surface insulating film 150 is provided as a planarization film, and may contribute to the color filter 180, the microlens 190, and the like being formed at a uniform height.

In some implementations, the surface insulating film 150 may be formed of a multi-layer film. As an example, unlike the shown example, the surface insulating film 150 may include an aluminum oxide film, a hafnium oxide film, a silicon oxide film, a silicon nitride film, and a hafnium oxide film that are sequentially stacked on the second surface 100b of the first substrate 100.

A grid film 160 may be formed on the surface insulating film 150. The grid film 160 may be formed in a lattice shape from a planar view point (e.g., the XY plane). For example, the grid film 160 may be disposed to overlap at least a part of the PD separation pattern 120 in the third direction Z.

In some implementations, the grid film 160 may include a first grid film 162 and a second grid film 164. The first grid film 162 and the second grid film 164 may be sequentially stacked on the surface insulating film 150.

The first grid film 162 may include, for example, but not limited to, at least one of titanium (Ti), titanium nitride (TiN), tantalum (Ta), tantalum nitride (TaN), tungsten (W), aluminum (Al), copper (Cu), and combinations thereof. The first grid film 162 may prevent electric charges generated by ESD (electrostatic discharge) or the like from being accumulated on the surface of the first substrate 100 (e.g., the second side 100b) to effectively prevent an ESD bruise defect.

The second grid film 164 may include a low refractive index material that has a lower refractive index than silicon (Si). For example, the second grid film 164 may include, but not limited to, at least one of silicon oxide, aluminum oxide, tantalum oxide, and combinations thereof. The second grid film 164 may improve the light collection efficiency of each of the unit pixels PX, by refracting or reflecting light obliquely incident on the second surface 100b, which is a photo-receiving surface.

A first protective film 166 may be formed on the surface insulating film 150 and the grid film 160. The first protective film 166 may extend conformally along the profiles of the surface insulating film 150 and the grid film 160. The first protective film 166 may prevent damage of the surface insulating film 150 and the grid film 160. The first protective film 166 may include, for example, but not limited to, aluminum oxide (AlO).

The color filter 180 may be formed on the first protective film 166. The color filter 180 may have various colors depending on the unit pixels. For example, the color filter 180 may include a red color filter, a green color filter, a blue color filter, a yellow filter, a magenta filter, and a cyan filter, and may further include a white filter.

A micro lens 190 may be formed on the color filter 180. The micro lens 190 has a convex shape, and may have a predetermined radius of curvature. Accordingly, the micro lens 190 may collect the light that is incident on the unit pixel PX. The micro lens 190 may include, for example, but not limited to, a light-transmitting resin.

A second protective film 195 may be formed on the micro lens 190. The second protective film 195 may extend along the surface of the micro lens 190. The second protective film 195 may include, for example, but not limited to, an inorganic oxide film such as a silicon oxide film, a titanium oxide film, a zirconium oxide film or a hafnium oxide film. As an example, the second protective film 195 may include low temperature oxide (LTO).

The second protective film 195 may protect the micro lens 190 from the outside. For example, the second protective film 195 may protect the micro lens 190 containing an organic material, by including an inorganic oxide film. Further, the second protective film 195 may improve the quality of the image sensor, by improving the light collection efficiency of the micro lens 190. For example, the second protective film 195 may reduce reflection, refraction, scattering, or the like of incident light that reaches the space between the micro lenses 190 by filling the space between the micro lenses 190.

FIG. 5 is a graph for explaining the performance of an image sensor according to some implementations. For reference, in FIG. 5, a horizontal axis represents a depth of the first substrate 100 measured between the first surface 100a and the second surface 100b, and a vertical axis represents the electrostatic potential of the first substrate 100. That is, FIG. 5 shows a change in electrostatic potential depending on the depth of the first substrate 100. Also, in FIG. 5, a comparative example was measured in an off-state of the transfer transistor TX for a unit pixel not having the control gate structure CGS, and an experimental example was measured in an off-state of the transfer transistor TX for a unit pixel to which a positive (+) bias voltage is applied to the control gate electrode CG.

Referring to FIGS. 1 to 5, the control gate structure CGS may control the electrostatic potential of the first substrate 100, using a voltage applied to the control gate electrode CG.

Specifically, as shown in FIG. 5, the photoelectric conversion region 101 in the first substrate 100 may include a potential control region CGR. The potential control region CGR may be a partial region of the photoelectric conversion region 101 adjacent to the control gate structure CGS. The first substrate 100 may also include a channel region TGR between the photoelectric conversion region 101 and the floating diffusion region FD. When comparing Comparative Example 1 with Experimental Example 1, it may be confirmed that the electrostatic potential of the potential control region CGR is significantly improved as a positive (+) bias voltage is applied to the control gate electrode CG. As a result, in the off-state of the transfer transistor TX, the difference between the electrostatic potential of the channel region TGR and the electrostatic potential of the potential control region CGR increases, and the full well capacity (FWC) of the photoelectric conversion element PD by the photoelectric conversion region 101 may be improved.

As the miniaturization of the unit pixels is constantly required, it is difficult to ensure FWC, which is a total amount of charges that the photoelectric conversion element may accommodate in the unit pixel. For example, the doping concentration of the photoelectric conversion region may be enhanced to achieve a high FWC in a miniaturized unit pixel, but the resulting increased process dispersion causes a decrease in the productivity of the image sensor.

The image sensor according to some implementations may provide improved performance even in miniaturized unit pixels using the control gate structure CGS. Specifically, as described above using FIG. 5, the control gate structure CGS may provide an improved FWC, using a voltage applied to the control gate electrode CG.

Furthermore, in some implementations, the control gate structure CGS may improve the transfer efficiency of the transfer transistor TX, using a voltage applied to the control gate electrode CG. For example, a negative (−) bias voltage may be applied to the control gate electrode CG at the time of the on-operation of the transfer transistor TX. Accordingly, the charges (i.e., electrons) generated from the photoelectric conversion element PD may be pushed out of the control gate structure CGS, and more easily transmitted toward the floating diffusion region FD.

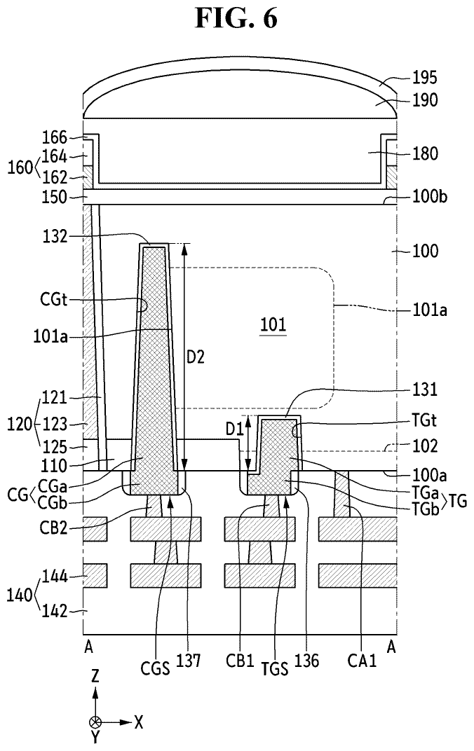

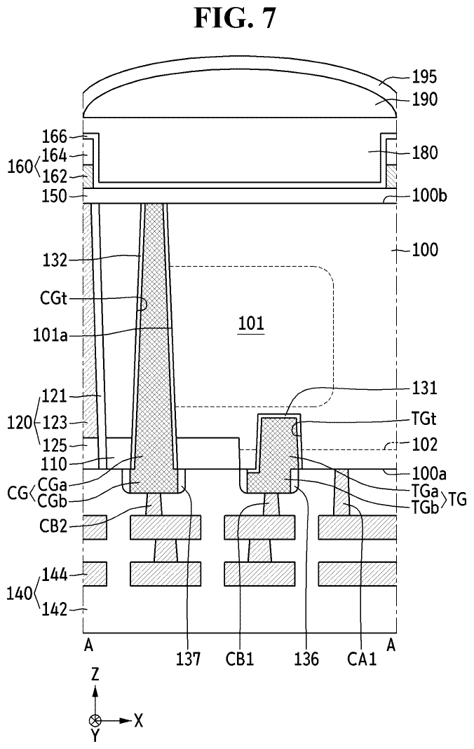

FIGS. 6 and 7 are various cross-sectional views for explaining an image sensor according to some implementations. For convenience of explanation, repeated parts of contents described above using FIGS. 1 to 5 will be briefly explained or omitted.

Referring to FIGS. 1, 2 and 6, in the image sensor according to some implementations, one end of the control gate structure CGS (e.g., the upper end of the control gate structure CGS in FIG. 6) is located at a level between the photoelectric conversion region 101 and the second surface 100b.

For example, as shown, on the basis of the first surface 100a, the depth D2 of the second gate trench CGt may be smaller than the maximum depth at which the photoelectric conversion region 101 is formed (e.g., the distance between the first surface 100a and the upper face of the photoelectric conversion region 101 in FIG. 6), and may be smaller than the thickness of the first substrate 100. In this case, the area of the photoelectric conversion region 101 adjacent to the control gate structure CGS increases, and the electrostatic potential of the first substrate 100 may be more effectively controlled.

Referring to FIGS. 1, 2, and 7, in the image sensor according to some implementations, the control gate structure CGS penetrates the first substrate 100.

For example, as shown, the control gate structure CGS may be adjacent to (or in contact with) both the first surface 100a and the second surface 100b. In this case, the area of the photoelectric conversion region 101 adjacent to the control gate structure CGS increases, and the electrostatic potential of the first substrate 100 may be more effectively controlled.

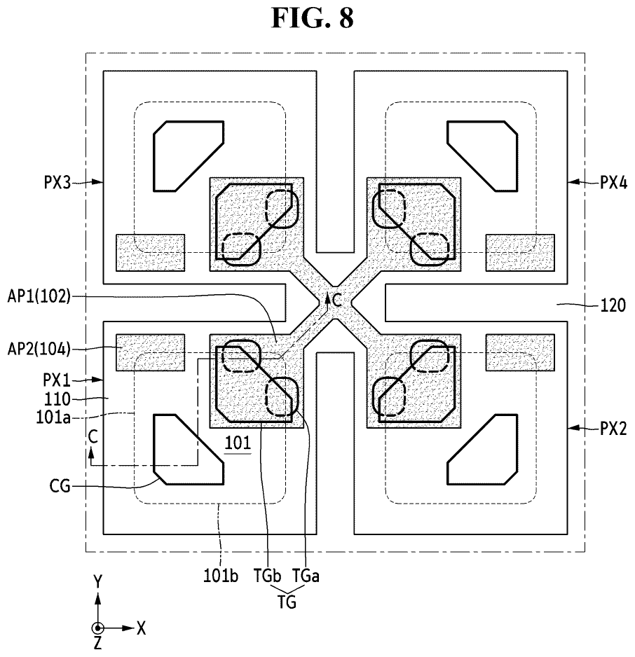

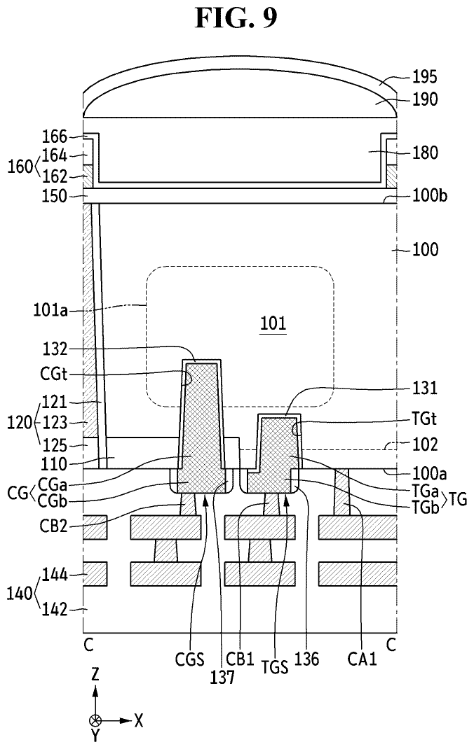

FIG. 8 is a plan view for explaining a pixel array of an image sensor according to some implementations. FIG. 9 is a schematic cross-sectional view taken along C-C of FIG. 8. For convenience of explanation, repeated parts of contents described above using FIGS. 1 to 7 are briefly explained or omitted.

Referring to FIGS. 1, 8, and 9, in the image sensor according to some implementations, the control gate structure CGS completely overlaps the photoelectric conversion region 101 in the third direction Z.

For example, as shown in FIG. 8, from a planar view point, the photoelectric conversion region 101 may completely surround the control gate structure CGS. In this case, the area of the photoelectric conversion region 101 adjacent to the control gate structure CGS increases, and the electrostatic potential of the first substrate 100 may be more effectively controlled.

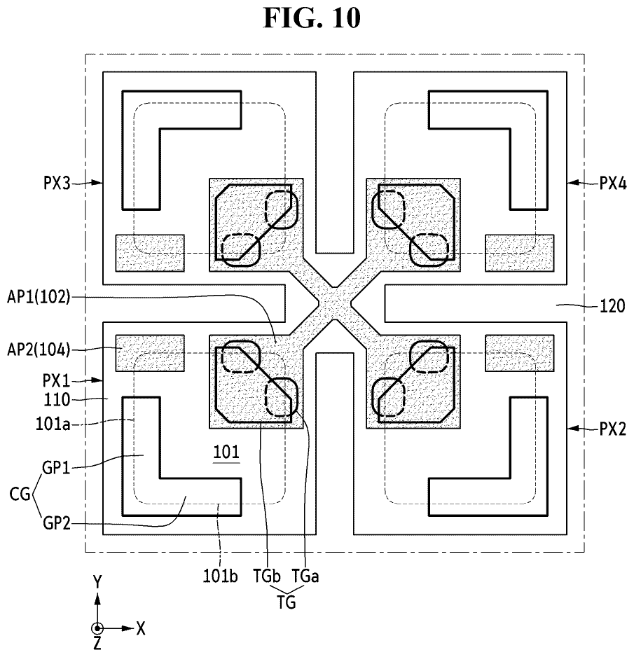

FIGS. 10 to 13 are various plan views for explaining a pixel array of the image sensor according to some implementations. For convenience of explanation, repeated parts of contents described above using FIGS. 1 to 9 will be briefly explained or omitted.

Referring to FIGS. 1 and 10, in the image sensor according to some implementations, the control gate electrode CG includes a first extension GP1 and a second extension GP2 that intersect each other.

For example, the first extension GP1 may extend long in the second direction Y, and the second extension GP2 may extend long in the first direction X. In some implementations, the first extension GP1 may be adjacent to the first side surface 101a of the photoelectric conversion region 101. In some implementations, the second extension GP2 may be adjacent to the second side surface 101b of the photoelectric conversion region 101. From a planar view point, the first extension GP1 and the second extension GP2 may extend along the periphery of the photoelectric conversion region 101 in an overall “L” shape. In this case, the area of the photoelectric conversion region 101 adjacent to the control gate electrode CG increases, and the electrostatic potential of the first substrate 100 may be more effectively controlled.

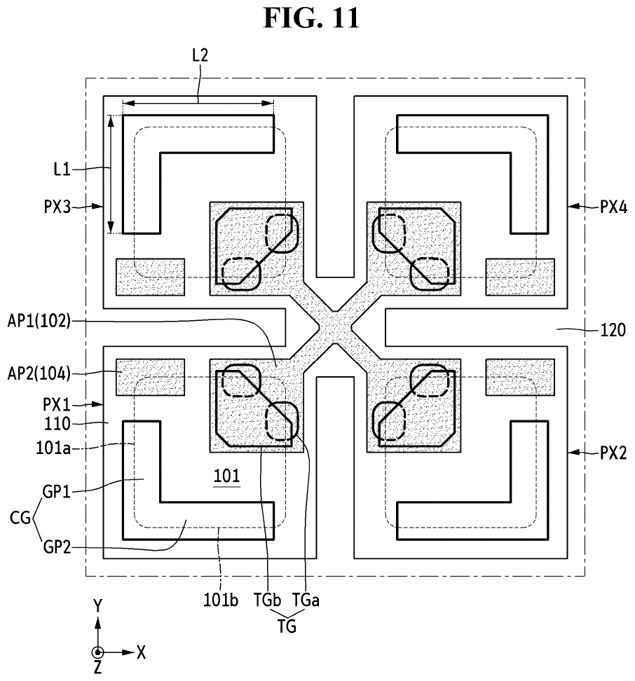

Referring to FIGS. 1 and 11, in the image sensor according to some implementations, the first extension GP1 and the second extension GP2 may extend at different lengths from each other.

For example, a length L1 of the first extension GP1 extending in the second direction Y may be shorter than a length L2 of the second extension GP2 extending in the first direction X. In some implementations, the second active pattern AP2 may be arranged together with the first extension GP1 along the second direction Y. In this case, the space efficiency of the control gate electrode CG in the miniaturized unit pixel PX may be enhanced.

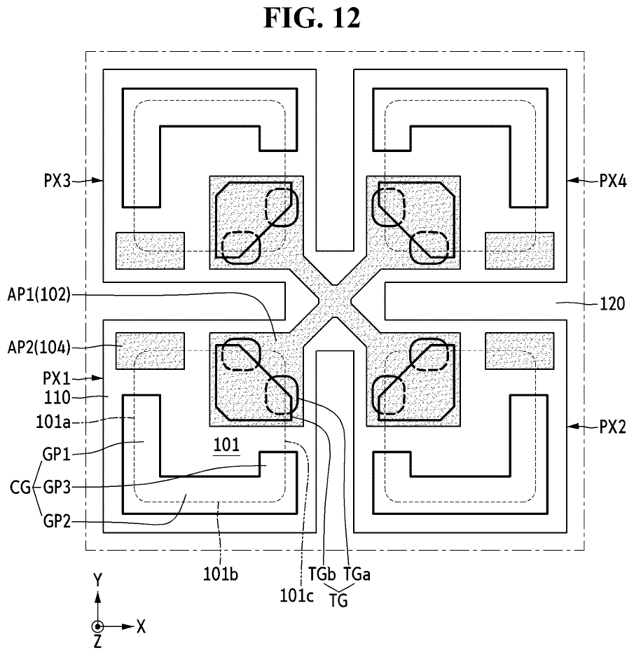

Referring to FIGS. 1 and 12, in the image sensor according to some implementations, the control gate electrode CG further includes a third extension GP3.

The third extension GP3 may face the first extension GP1. For example, each of the first extension GP1 and the third extension GP3 may extend in the second direction Y from both ends of the second extension GP2. In some implementations, the photoelectric conversion region 101 may further include a third side surface 101c that is opposite to the first side surface 101a. As an example, the third side surface 101c may intersect the first direction X. The third extension GP3 may be adjacent to the third side surface 101c. From a planar view point, the first extension GP1, the second extension GP2, and the third extension GP3 may extend along the periphery of the photoelectric conversion region 101 in an overall “C” shape. In this case, the area of the photoelectric conversion region 101 adjacent to the control gate electrode CG increases, and the electrostatic potential of the first substrate 100 may be more effectively controlled.

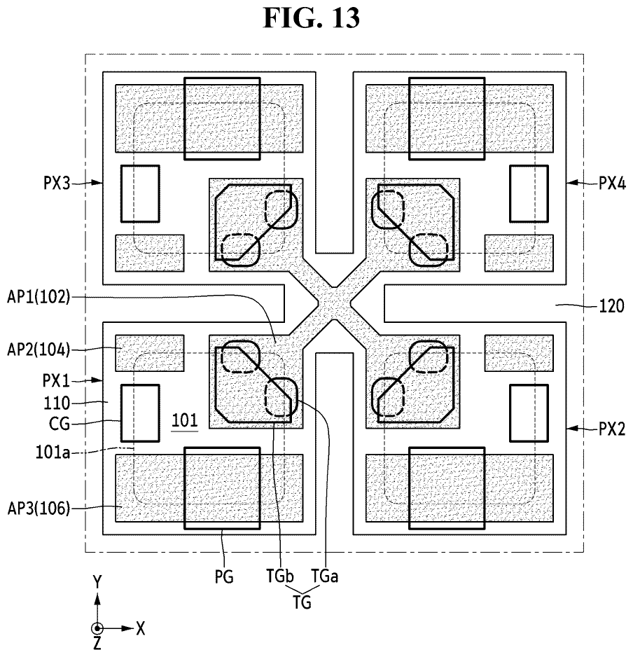

Referring to FIGS. 1 and 13, the image sensor according to some implementations further includes a third impurity region 106 and a pixel gate electrode PG.

For example, the active regions AP1, AP2, and AP3 of each of the pixel regions PX1 to PX4 may further include a third active pattern AP3. The third active pattern AP3 may be separated from the first active pattern AP1 and the second active pattern AP2 by the element separation pattern 110. The third impurity region 106 may be formed in the third active pattern AP3. The shapes, sizes, numbers, placement and the like of the active regions AP1, AP2, and AP3 are merely exemplary, and are not limited to those shown in the drawings.

The third impurity region 106 may have the second conductivity type. For example, the third impurity region 106 may be an n-type impurity region formed by ion-implantation of n-type impurities into the third active pattern AP3. The third impurity region 106 may be spaced apart from the photoelectric conversion region 101.

The pixel gate electrode PG may be formed on the third active pattern AP3. The pixel gate electrode PG may be adjacent to the third impurity region 106. For example, the third impurity region 106 may be formed in the third active pattern AP3 on a side surface of the pixel gate electrode PG.

The pixel gate electrode PG may include various transistors for processing an electrical signal generated from the photoelectric conversion element PD by the photoelectric conversion region 101. For example, the pixel gate electrode PG may be provided as at least one gate among the reset transistor RX, the drive transistor DX or the selection transistor SX of FIG. 1.

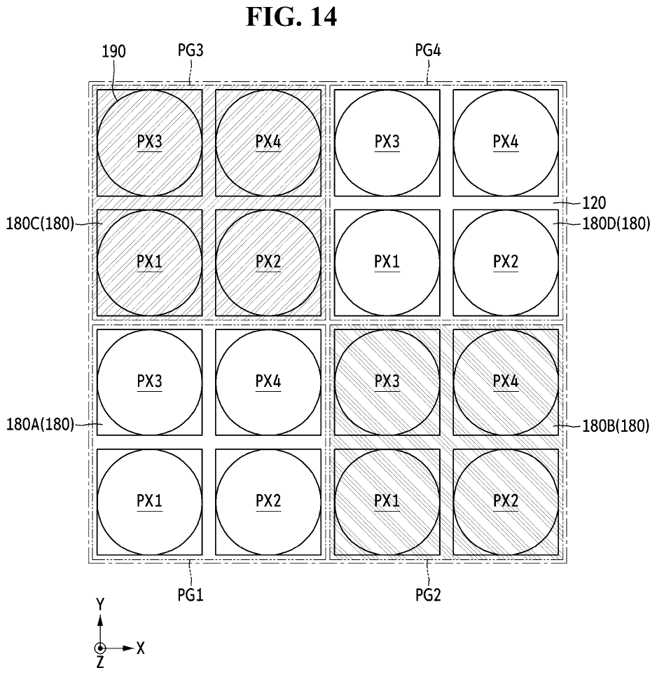

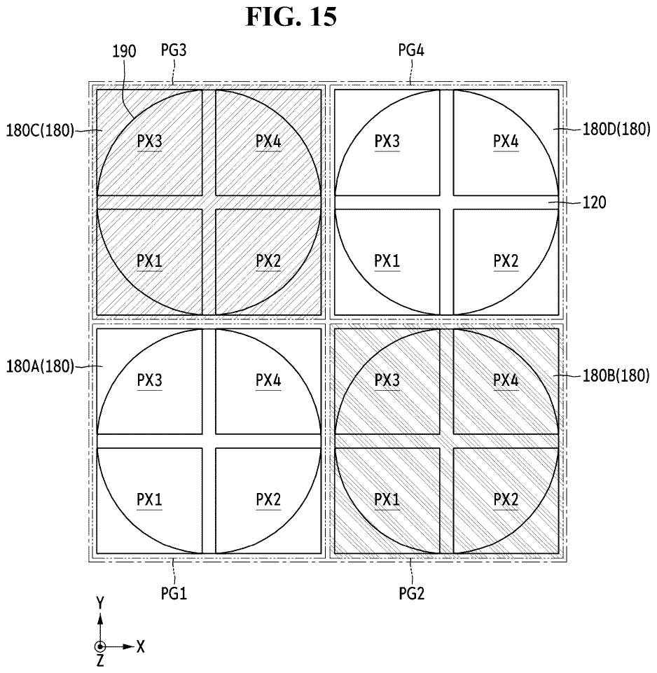

FIGS. 14 and 15 are various layout diagrams for explaining a pixel array of an image sensor according to some implementations. For convenience of explanation, repeated parts of contents described above using FIGS. 1 to 13 will be briefly explained or omitted.

Referring to FIGS. 14 and 15, the image sensor according to some implementations includes a plurality of pixel groups PG1 to PG4.

For example, the pixel groups PG1 to PG4 may include a first pixel group PG1, a second pixel group PG2, a third pixel group PG3, and a fourth pixel group PG4 that are adjacent to each other. The first pixel group PG1 and the second pixel group PG2 may be adjacent to each other in the first direction X. The first pixel group PG1 and the third pixel group PG3 may be adjacent to each other in the second direction Y that intersects the first direction X. The second pixel group PG2 and the fourth pixel group PG4 may be adjacent to each other in the second direction Y, and the third pixel group PG3 and the fourth pixel group PG4 may be adjacent to each other in the first direction X. That is, the first pixel group PG1 and the fourth pixel group PG4 may be adjacent to each other in a diagonal direction between the first direction X and the second direction Y.

Each of the pixel groups PG1 to PG4 may include a plurality of unit pixels PX. For example, each of the pixel groups PG1 to PG4 may include the pixel regions PX1 to PX4 described above using FIGS. 1 to 5.

In some implementations, the pixel regions PX1 to PX4 included in each of the pixel groups PG1 to PG4 may share the color filter 180 of the same color. Furthermore, the adjacent pixel groups PG1 to PG4 may have the color filters 180 of different colors. For example, the pixel groups PG1 to PG4 may include color filters 180 arranged in the form of a Bayer pattern. As an example, the second pixel group PG1 may include a red color filter 180B, and the third pixel group PG3 may include a blue color filter 180C. The first pixel group PG1 and the fourth pixel group PG4 may include green color filters 180A and 180D, respectively.

Referring to FIG. 13, in the image sensor according to some implementations, the pixel regions PX1 to PX4 included in each of the pixel groups PG1 to PG4 may share one microlens 190.

For example, the plurality of micro lens 190 may be arranged to correspond to the plurality of pixel groups PG1 to PG4. Accordingly, each of the pixel groups PG1 to PG4 may provide an auto-focus (AF) function. As an example, the first pixel group G1 may provide a phase detection AF (PDAF) function, using the photoelectric conversion region 101 divided into the pixel regions PX1 to PX4.

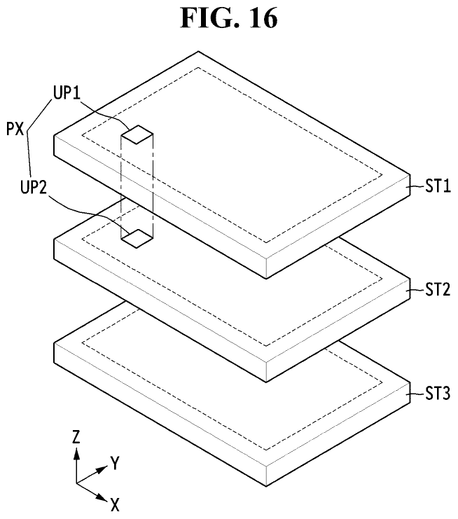

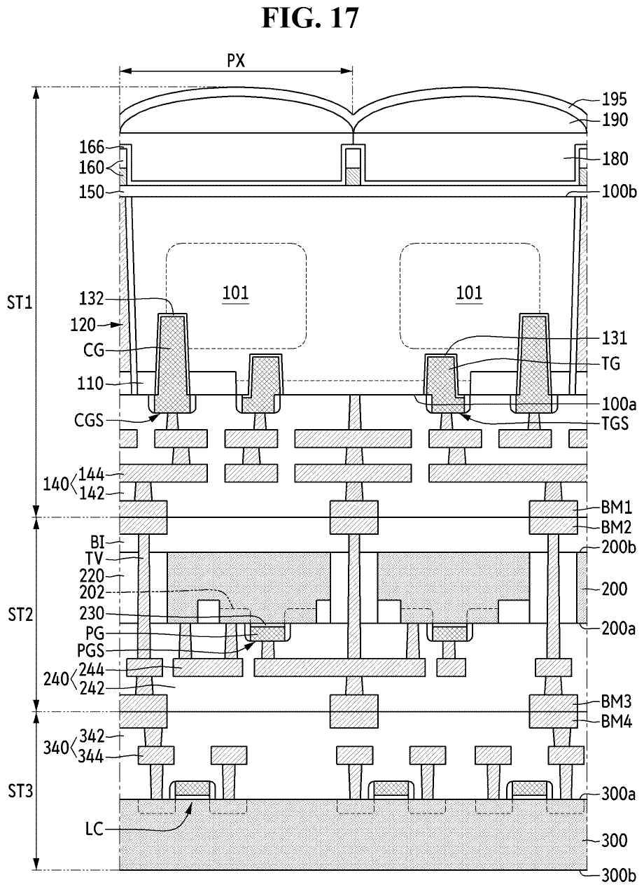

FIG. 16 is a schematically exploded perspective view for explaining an image sensor according to some implementations. FIG. 17 is a schematic cross-sectional view for explaining the image sensor of FIG. 16. For convenience of explanation, repeated parts of contents described above using FIGS. 1 to 15 will be briefly explained or omitted.

Referring to FIGS. 16 and 17, the image sensor according to some implementations includes a first stack ST1, a second stack ST2, and a third stack ST3 that are stacked in order.

The first stack ST1 may include a first substrate 100. In addition, the first stack ST1 may include a plurality of upper pixels UP1 each including a photoelectric conversion region 101 in the first substrate 100. For example, the first stack ST1 may include the first substrate 100, the element separation pattern 110, the PD separation pattern 120, the photoelectric conversion region 101, the first impurity region 102, the second impurity region 104, the transfer gate structure TGS, the control gate structure CGS, the first wiring structure 140, the surface insulating film 150, the grid film 160, the color filter 180, and the microlens 190 described above using FIGS. 1 to 5.

The second stack ST2 may include a plurality of lower pixels UP2 corresponding to a plurality of upper pixels UP1. The upper pixel UP1 and the lower pixel UP2 may form one unit pixel PX. For example, the second stack ST2 may include a second substrate 200, a fourth impurity region 202, a pixel gate structure PGS, and a second wiring structure 240.

The second substrate 200 may be a semiconductor substrate. For example, the second substrate 200 may be bulk silicon or silicon-on-insulator (SOI). The second substrate 200 may be a silicon substrate, or may include other materials, for example, silicon germanium, indium antimonide, lead telluride, indium arsenide, indium phosphide, gallium arsenide or gallium antimonide. Alternatively, the second substrate 200 may be one in which an epitaxial layer is formed on a base substrate.

The second substrate 200 may include a third surface 200a and a fourth surface 200b that are opposite to each other. In the implementations to be described below, the third surface 200a is also referred to as a front side of the second substrate 200, and the fourth surface 200b may be referred to as a back side of the second substrate 200.

The fourth impurity region 202 may be formed in the second substrate 200 adjacent to the third surface 200a. For example, the fourth impurity region 202 may be an n-type impurity region formed by ion-implantation of n-type impurities into the second substrate 200.

The pixel gate structure PGS may be formed on the third surface 200a of the second substrate 200. The pixel gate structure PGS may be adjacent to the fourth impurity region 202. For example, the fourth impurity region 202 may be formed in the second substrate 200 on a side surface of the pixel gate structure PGS.

In some implementations, the pixel gate structure PGS may include a pixel gate dielectric film 230 and a pixel gate electrode PG.

The pixel gate dielectric film 230 may be interposed between the second substrate 200 and the pixel gate electrode PG. The pixel gate dielectric film 230 may include at least one of a dielectric material, for example, silicon oxide, silicon oxynitride, silicon nitride, or a high-k material having a dielectric constant greater than that of silicon oxide. The pixel gate dielectric film 230 may include the same material as the transfer gate dielectric film 131, or may include a different material from the transfer gate dielectric film 131.

The pixel gate electrode PG may be stacked on the pixel gate dielectric film 230. The pixel gate electrode PG may include a conductive material, for example, but not limited to, at least one of a metal film, a metal silicide film, an undoped polysilicon film, an undoped silicon germanium film, an impurity-doped polysilicon film, or an impurity-doped silicon germanium film. The pixel gate electrode PG may include the same material as the transfer gate electrode TG, and may include a material different from the transfer gate electrode TG. The pixel gate electrode PG may be provided as a gate of at least one of the reset transistor RX, the drive transistor DX, or the selection transistor SX of FIG. 1. As an example, the first impurity region 102 of the first stack ST1 provided as the floating diffusion region FD may be electrically connected to the fourth impurity region 202 of the second stack ST2 and/or the pixel gate electrode PG of the second stack ST2.

The second wiring structure 240 may be formed on the third surface 200a of the second substrate 200. The second wiring structure 240 may include a plurality of wiring patterns. For example, the second wiring structure 240 may include a second inter-wiring insulating film 242 on the third surface 200a, and second wiring patterns 244 in the second inter-wiring insulating film 242. The second wiring structure 240 may be electrically connected to the fourth impurity region 202 and/or the pixel gate structure PGS. In FIG. 17, the shape, placement, number of layers, and the like of the second wiring pattern 244 are merely exemplary and are not limited thereto.

In some implementations, the first stack ST1 and the second stack ST2 may be stacked in a C2C (Chip to Chip) structure. The C2C structure may mean a structure in which an upper chip including the first stack ST1 is manufactured on a first wafer and a lower chip including the second stack ST2 is manufactured on a second wafer different from the first wafer, and then the upper chip and the lower chip are connected to each other by a bonding way.

As an example, the bonding way may mean a way of connecting a first bonding metal BM1 of the upper chip and a second bonding metal BM2 of the lower chip to each other. For example, when the first bonding metal BM1 and the second bonding metal BM2 are formed of copper (Cu), the bonding method may be a Cu-Cu bonding way. However, this is merely exemplary, and it goes without saying that the first bonding metal BM1 and the second bonding metal BM2 may be formed of various other metals, such as aluminum (Al) or tungsten (W). As the first bonding metal BM1 and the second bonding metal BM2 are bonded, the first stack ST1 and the second stack ST2 may be electrically connected to each other.

In some implementations, the fourth surface 200b of the second substrate 200 may face the first surface 100a of the first substrate 100. For example, the first stack ST1 and the second stack ST2 may be bonded in a frontside to backside (F2B) way.

In some implementations, a buried insulating film BI may be formed on the fourth surface 200b of the second substrate 200. The buried insulating film BI may be interposed between the second substrate 200 and the first wiring structure 140. For example, the second substrate 200 may be a silicon-on-insulator (SOI) substrate on the buried insulating film BI. The second bonding metal BM2 may be formed in the buried insulating film BI.

In some implementations, the second stack ST2 may further include a through via TV. The through via TV may penetrate the second substrate 200 to electrically connect the second wiring structure 240 and the second bonding metal BM2. For example, an insulating pattern 220 may be formed in the second substrate 200. The insulating pattern 220 may form an insulating region in the second substrate 200. The through via TV may penetrate the insulating pattern 220 to connect the second wiring structure 240 and the second bonding metal BM2.

The third stack ST3 may include a third substrate 300, logic circuit elements LC, and a third wiring structure 340.

The third substrate 300 may be a semiconductor substrate. For example, the third substrate 300 may be bulk silicon or silicon-on-insulator (SOI). The third substrate 300 may be a silicon substrate or may include other materials, for example, silicon germanium, indium antimonide, lead telluride, indium arsenide, indium phosphide, gallium arsenide or gallium antimonide. Alternatively, the third substrate 300 may be one in which an epitaxial layer is formed on a base substrate.

The third substrate 300 may include a fifth surface 300a and a sixth surface 300b that are opposite to each other. In the implementations to be described below, the fifth surface 300a may also be referred to as a front side of the third substrate 300, and the sixth surface 300b may also be referred to as a back side of the third substrate 300.

The logic circuit elements LC may be formed on the fifth surface 300a of the third substrate 300. The logic circuit element LC may include, but not limited to, a logic circuit for controlling each unit pixel PX, for example, a power circuit, an input/output interface, and/or an image signal processor.

The third wiring structure 340 may be formed on the fifth surface 300a of the third substrate 300. The third wiring structure 340 may include a plurality of wiring patterns. For example, the third wiring structure 340 may include a third inter-wiring insulating film 342 on the fifth surface 300a, and third wiring patterns 344 in the third inter-wiring insulating film 342. The third wiring structure 340 may be electrically connected to the logic circuit elements LC. In FIG. 17, the shape, placement, number of layers, and the like of the third wiring pattern 344 are merely exemplary and are not limited thereto.

In some implementations, the second stack ST2 and the third stack ST3 may be stacked in a C2C (Chip to Chip) structure. The C2C structure means that an upper chip including the second stack ST2 is manufactured on a second wafer, a lower chip including the third stack ST3 is manufactured on a third wafer different from the second wafer, and then the upper chip and the lower chip are connected to each other by the bonding way.

As an example, the bonding way may refer to a way of connecting the third bonding metal BM3 of the upper chip and the fourth bonding metal BM4 of the lower chip to each other. For example, when the third bonding metal BM3 and the fourth bonding metal BM4 are formed of copper (Cu), the bonding way may be a Cu-Cu bonding way. However, this is merely exemplary, and it goes without saying that the third bonding metal BM3 and the fourth bonding metal BM4 may be formed of various other metals such as aluminum (Al) or tungsten (W). As the third bonding metal BM3 and the fourth bonding metal BM4 are bonded, the second stack ST2 and the third stack ST3 may be electrically connected to each other.

In some implementations, the fifth surface 300a of the third substrate 300 may face the third surface 200a of the second substrate 200. For example, the second stack ST2 and the third stack ST3 may be bonded in a frontside to backside (F2F) way.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. An image sensor comprising:
a substrate comprising a first surface and a second surface opposing the first surface;
a first pixel region comprising a first photoelectric conversion region (PD) in the substrate;
a second pixel region comprising a second photoelectric conversion region (PD) in the substrate;
a PD separation pattern between the first PD and the second PD;
a transfer gate structure comprising a first lower part extending into the substrate from the first surface, and a first upper part protruding beyond the first surface; and
a control gate structure comprising a second lower part extending into the substrate from the first surface, and a second upper part protruding beyond the first surface,
wherein the PD separation pattern penetrates the substrate,
wherein the first upper part is spaced apart from the second upper part in a first direction parallel to the first surface,
wherein the transfer gate structure and the control gate structure are disposed in the first pixel region, and
wherein the image sensor is configured to receive light from the second surface.

2. The image sensor of claim 1, further comprising:
a first contact vertically connected to the transfer gate structure in a second direction perpendicular to the first direction; and
a second contact vertically connected to the control gate structure in the second direction,
wherein the first contact is spaced apart from the second contact in the first direction.

3. The image sensor of claim 2, further comprising:
a wiring structure comprising a plurality of wiring patterns including a first wiring pattern and a second wiring pattern,
wherein the first wiring pattern and the second wiring pattern are disposed at a closest distance from the first surface in the second direction among the plurality of wiring patterns,
wherein the first contact is directly connected to the first wiring pattern, and
wherein the second contact is directly connected to the second wiring pattern.

4. The image sensor of claim 2, wherein the control gate structure is configured to receive a voltage from the second contact.

5. The image sensor of claim 1,
wherein the first lower part has a first height from the first surface in a second direction perpendicular to the first direction,
wherein the second lower part has s second height from the first surface in the second direction, and
wherein the first height is different from the second height.

6. The image sensor of claim 5, wherein the second height is greater than the first height.

7. The image sensor of claim 1, wherein a width of the first lower part at the first surface in the first direction varies from −10% to +10% of a width of the second lower part at the first surface in the first direction.

8. The image sensor of claim 7, wherein the width of the first lower part at the first surface in the first direction varies from −5% to +5% of the width of the second lower part at the first surface in the first direction.

9. The image sensor of claim 1, further comprising:
an element separation pattern between the first lower part and the second lower part.

10. The image sensor of claim 9,
wherein the first lower part has a first height from the first surface in a second direction perpendicular to the first direction,
wherein the element separation pattern has s second height from the first surface in the second direction, and
wherein the first height is greater than the second height.

11. The image sensor of claim 1, wherein a width of the first upper part at the first surface in the first direction varies from −10% to +10% of a width of the second upper part at the first surface in the first direction.

12. The image sensor of claim 10, wherein the width of the first upper part at the first surface in the first direction varies from −5% to +5% of the width of the second upper part at the first surface in the first direction.

13. An image sensor comprising:
a substrate comprising a first surface and a second surface opposing the first surface;
a first pixel region comprising a first photoelectric conversion region (PD) in the substrate;
a second pixel region comprising a second photoelectric conversion region (PD) in the substrate;
a third pixel region comprising a third photoelectric conversion region (PD) in the substrate;
a fourth pixel region comprising a fourth photoelectric conversion region (PD) in the substrate;
a PD separation pattern separating the first to fourth PDs to each other;
a single color filter on the first to fourth PDs;
a floating diffusion region configured to store photocharges generated by the first to fourth PDs;
a first transfer gate structure comprising a first lower part extending into the substrate from the first surface, and a first upper part protruding beyond the first surface; and
a first control gate structure comprising a second lower part extending into the substrate from the first surface, and a second upper part protruding beyond the first surface,
wherein the PD separation pattern penetrates the substrate,
wherein the first upper part is spaced apart from the second upper part in a first direction parallel to the first surface,
wherein the first transfer gate structure and the first control gate structure are disposed in the first pixel region,
wherein the first to fourth pixel regions are sequentially arranged in a clockwise direction in a plan view, and
wherein the image sensor is configured to receive light from the second surface.

14. The image sensor of claim 13, further comprising:
a second transfer gate disposed in the second pixel region, wherein the first transfer gate is disposed at a right bottom corner area of the first pixel region in the plan view, and
wherein the second transfer gate is disposed at a left bottom corner area of the second pixel region in the plan view.

15. The image sensor of claim 14,
wherein the second pixel region is disposed in a second direction from the first pixel region, and
wherein the first direction is not perpendicular or parallel to the second direction.

16. The image sensor of claim 15, further comprising:
a first contact vertically connected to the first transfer gate structure in a third direction perpendicular to the first direction; and
a second contact vertically connected to the first control gate structure in the third direction,
wherein the first contact is spaced apart from the second contact in the first direction.

17. The image sensor of claim 16, further comprising:
a wiring structure comprising a plurality of wiring patterns including a first wiring pattern and a second wiring pattern,
wherein the first wiring pattern and the second wiring pattern are disposed at a closest distance from the first surface in the third direction among the plurality of wiring patterns,
wherein the first contact is directly connected to the first wiring pattern, and
wherein the second contact is directly connected to the second wiring pattern.

18. The image sensor of claim 17, wherein the first control gate structure is configured to receive a voltage from the second contact.

19. The image sensor of claim 18,
wherein the first lower part has a first height from the first surface in the third direction,
wherein the second lower part has s second height from the first surface in the third direction, and
wherein the first height is different from the second height.

20. The image sensor of claim 19, wherein the second height is greater than the first height.
